(19) United States
(12) Patent Application Publication
(10) Pub. No.: US 2026/0197982 A1
(43) Pub. Date: Jul. 9, 2026

(54) DOUBLE SIDED DISPLAY ASSEMBLY WITH BI-DIRECTIONAL FLOW THROUGH A COMMON, PARTITIONED HEAT EXCHANGER

(71) Applicant: Manufacturing Resources International, Inc., Alpharetta, GA (US)

(72) Inventor: Kevin O'Connor, Duluth, GA (US)

(21) Appl. No.: 19/550,838

(22) Filed: Feb. 26, 2026

Related U.S. Application Data
(63) Continuation of application No. 18/408,317, filed on Jan. 9, 2024, now Pat. No. 12,598,727.

(51) Int. Cl. H05K 7/20; G09F 9/302

(52) U.S. Cl. CPC H05K 7/20972; G09F 9/302; H05K 7/20436

(57) ABSTRACT

Display assemblies with bi-directional flow through a common, partition heat exchanger are provided. Side assemblies are connected to portions of a structural framework and each include a cover, an electronic display, and a channel for airflow, the electronic display and channel being located rearward of the cover. A heat exchanger is positioned rearward of the side assemblies. Septa airflow channels extend from the side assemblies and/or the structural framework to the heat exchanger. Rear airflow channels extend between the heat exchanger and the side assemblies, and are further defined, at least in part, by at least one of the septa airflow channels.

### CROSS-REFERENCE TO RELATED APPLICATIONS

This application is a continuation of U.S. application Ser. No. 18/408,317 filed Jan. 9, 2024, the disclosures of which are hereby incorporated by reference as if fully restated herein.

### TECHNICAL FIELD

Exemplary embodiments relate generally to double sided display assemblies with bi-directional flow through a common, partitioned heat exchanger as well as systems and methods related to the same.

### BACKGROUND AND SUMMARY OF THE INVENTION

Digital out of home (DOOH) advertising is becoming increasingly common. To accomplish such DOOH advertising, electronic displays are sometime placed within ruggedized housings to help the sensitive electronics withstand relatively harsh and varied environmental conditions. This may require at least partial enclosure and/or sealing of such units. The units themselves and/or ambient conditions (e.g., sunlight) may generate heat within the units. As the units may be at least partially sealed, thermal management systems are often needed to maintain internal temperatures and other conditions at acceptable levels, such as to accommodate the relatively sensitive electronic equipment located therein. It is known to use a combination of open loop(s) of ambient air and closed loop(s) of circulating gas to thermally manage displays. Examples of such units and known thermal management systems include the BOLDVU® display assemblies available from Manufacturing Resources International, Inc. of Alpharetta, Georgia (https://mri-inc.net/, Applicant for the Present Application).

Different components and desired unit profiles may require different components and/or component arrangements. For example, differing components and/or arrangements may affect airflow patterns and/or heat loading. This sometimes necessitates various thermal management considerations and designs.

A double-sided display assembly with bi-directional flow through a common, partitioned heat exchanger is provided along with related systems and methods. Side assemblies are connected to a structural framework. The side assemblies may be the same or substantially similar.

Each side assembly includes one or more channels, such as at least one closed loop channel. A rear channel between the side assemblies includes a common heat exchanger. Speta may extend within the rear channel to guide airflow. In exemplary embodiments, fan(s) drive circulating gas through a closed loop airflow pathway such that circulating gas exiting the at least one closed loop channel of a first one of the side assemblies is confined by a first set of one or more septa to travel into a distal portion of a closed loop portion of the heat exchanger before traveling along a rear surface of the second one of the side assembles in an opposing direction to an entrance to the at least one closed loop channel of a second one of the side assemblies. The circulating gas exiting the at least one closed loop channel of the second one of the side assemblies is confined by a second set of one or more septa to travel through a second portion of the closed loop portion of the heat exchanger distal from the second one of the side assemblies before traveling along a rear surface of the first one of the side assembles in an opposing direction to the entrance to the at least one closed loop channel of the first one of the side assemblies. In this fashion, the closed loop airflow pathway forms a loop within the unit. The septa and the heat exchanger may serve to partition the rear channel to separate portions of the loop. The closed loop airflow pathway may form a generally “S” or “Z” shape with parallel S's or Z's, and/or if the S or Z is considered as a bubble type such letter.

The at least one closed loop channel of each of the side assemblies may include a forward channel between a cover and display layer of an electronic display for the side assembly and a secondary channel between an illumination structure and the electronic display layer of the electronic display for the side assembly. While the circulating gas through the forward and rearward channels of a respective side assembly may extend substantially parallel, the flow(s) through the at least one closed loop channel of each respective side assembly may travel in opposing directions. The circulating gas flow(s) through the first and second portions of the closed loop portion of the heat exchanger may travel in opposing directions. The flows through the rear portions of the rear channel may extend in opposing directions.

One or more open loop airflow pathways may include at least one open loop channel provided at each of the side assemblies and an open loop portion of the heat exchanger.

Separations within the closed loop and/or between the closed loop and the ambient environment, any open loop airflow pathways, and/or other portions of the unit need not be perfect. For example, a hermetic seal is not necessarily required. Instead, separation may be in accordance with ingress protection code 65 or higher, for example.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical, similar, or equivalent features, and wherein:

FIG. 1 is perspective view of an exemplary display assembly in accordance with the present invention;

FIG. 2 is a top sectional view taken along section line A-A and illustrating an exemplary airflow pathway and airflow velocities within the display assembly when fans are activated;

FIG. 3 is the top sectional view of FIG. 2 with the exemplary airflow pathway illustrated in isolation; and

FIG. 4 is the top sectional view of FIG. 2 with exemplary airflow velocities illustrated in isolation.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

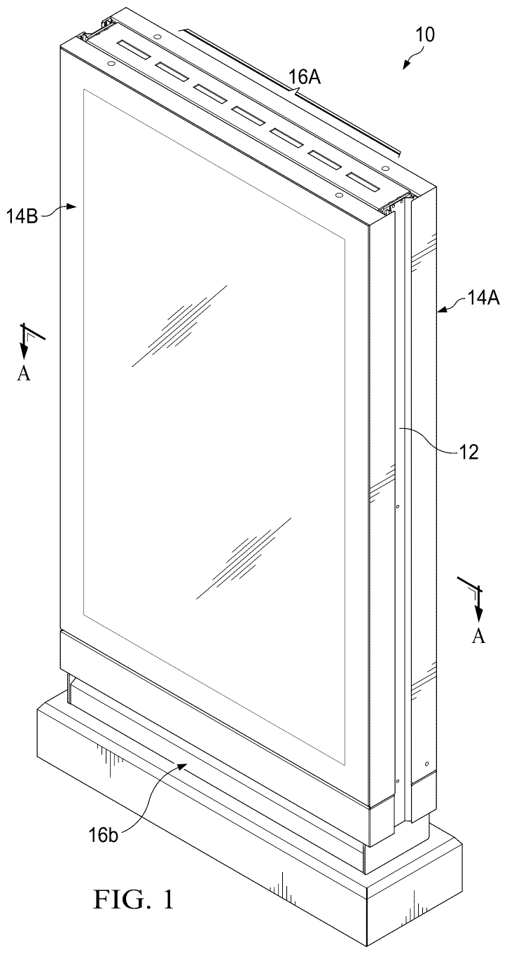

FIG. 1 illustrates an exemplary display unit 10 in accordance with the present invention. The unit 10 may comprise a first side assembly 14A and a second side assembly 14B connected to a structural framework 12. The first and second side assemblies 14A, 14B may be mounted to opposing sides of the framework 12. The framework 12 may include one or more structural members, panels, combinations thereof, or the like. The framework 12 may be configured for mounting to a ground surface (e.g., sidewalk, parking lot, etc.), street furniture (e.g., bus shelter, railing, pole, etc.), combinations thereof, or the like, and/or may incorporate the same.

Any number and/or arrangement of the side assemblies 14 and framework 12 may be utilized. While each side assembly 14 comprises an electronic display in exemplary embodiments, such is not necessarily required. For example, one or more of the side assemblies may include a poster cavity (illuminated or otherwise), door/access panel, combinations thereof, or the like in other exemplary embodiments, while preferably including similar structure (e.g., panels) to provide the associated airflow pathway(s) shown and/or described herein.

In exemplary embodiments, without limitation, the side assemblies 14 are movably mounted to the framework 12, such as by way of hinges located along an upper portion or side of the side assemblies 14 to allow rotation about a substantially (e.g., within 20 degrees) horizontal or vertical axis, gas struts, single or multi-arm linkages, combinations thereof, or the like. This may permit servicing of the unit 10, such as internal components and/or side assemblies 14, including on site servicing, interchange and/or replacement.

Intakes and/or exhausts 16 may be provided at the framework 12 and/or the side assemblies 14 for ingesting and/or exhausting ambient air. For example, without limitation, a common or separate intake(s) 16A may be provided at an upper portion of the framework 12 for the side assemblies 14 and/or heat exchanger 38 while separate, dedicated exhausts 16B are provided at a lower portion of each side assembly 14 and/or the heat exchanger 38. Various common and/or separate intakes and/or exhausts 16 may be utilized for one or more of the side assemblies 14 and/or heat exchanger 38. The number and/or arrangement of intakes/exhausts 16 is exemplary and not intended to be limiting. Internal intakes/exhausts may be provided for moving air into and/or out of each of the side assemblies 14. The intakes and/or exhausts 16 may ingest and/or exhaust ambient air through one or more open loop airflow pathways within the unit 10 as further discussed herein.

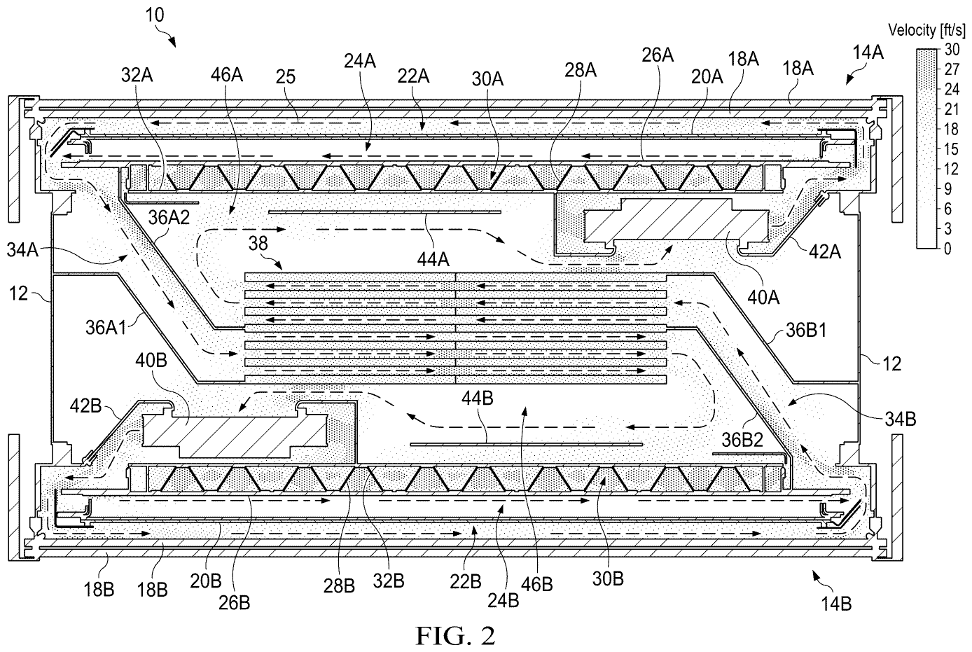

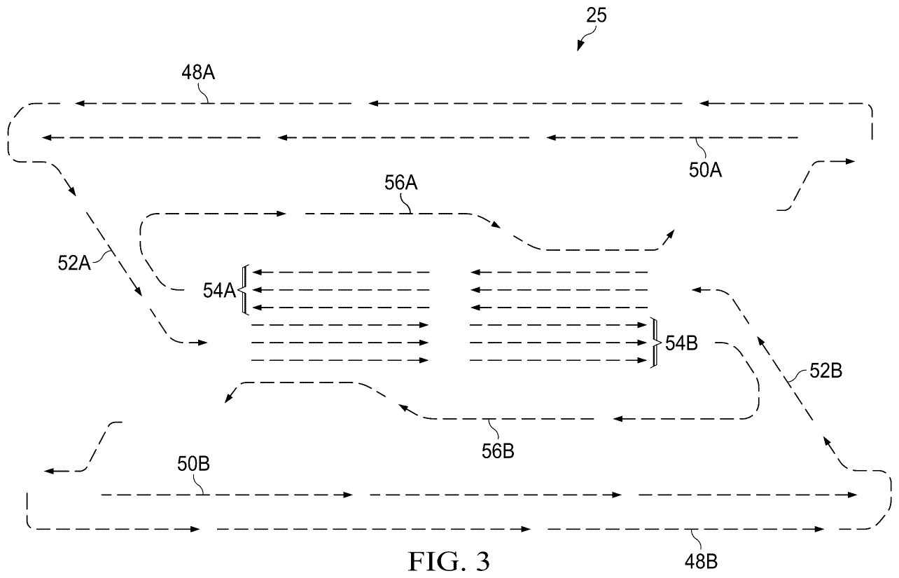

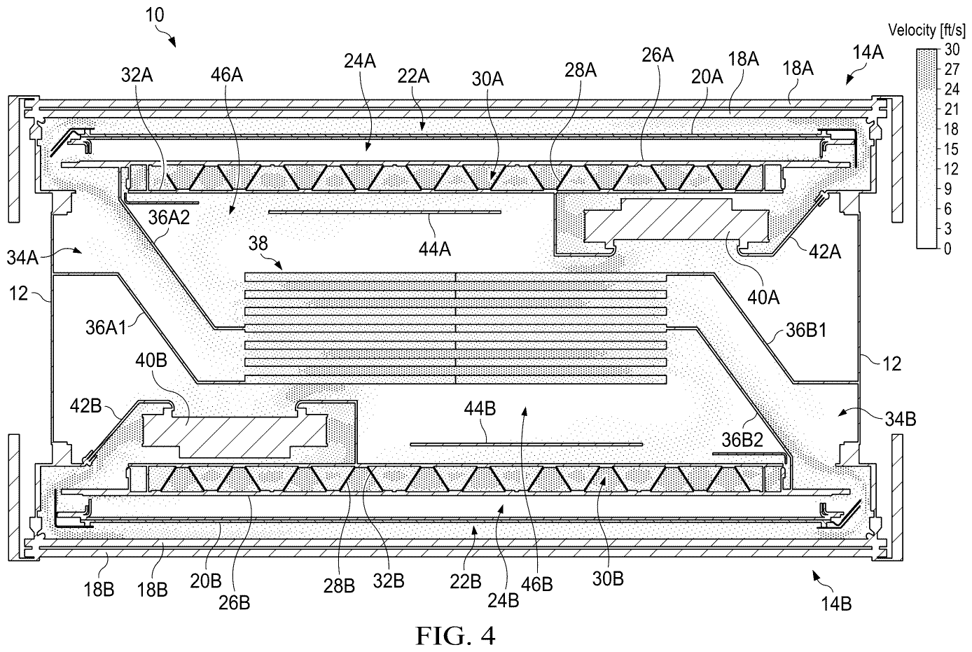

FIG. 2 through FIG. 4 illustrate exemplary sectional views of the unit 10. More specifically, FIG. 2 illustrates an exemplary sectional view with structural components, exemplary airflow velocities, and an exemplary generalized closed loop airflow pathway 25 illustrated. FIG. 3 illustrates the generalized closed loop airflow pathway 25 in isolation for ease of viewing. FIG. 4 illustrates the structural components and exemplary airflow velocities in isolation for ease of viewing.

Each of the side assemblies 14A, 14B may be the same or substantially similar in exemplary embodiments, without limitation. This may reduce part count and make replacement easy. The side assemblies 14A, 14B may be numbered similarly but with an “A” or “B” designator. The side assemblies 14A, 14B and/or their components may be referred to by their base designator herein (e.g., 14A, 14B as 14, 18A, 18B as 18, etc.).

Each of the side assemblies 14 may comprise a cover 18. The covers 18A, 18B may each comprise a single or multiple layers. The covers 18 may be transparent or translucent. The cover 18 layers may comprise glass, acrylic, one or more polymers, combinations thereof, or the like. The covers 18 may comprise one or more polarizers, anti-reflection films, combinations thereof, or the like.

An electronic display layer 20A, 20B may be positioned rearward of each of the covers 18A, 18B, respectively. The electronic display layers 20 may comprise liquid crystals, though other types of electronic displays and/or electronic display layers 20 may be utilized (e.g., OLED). The electronic display layers 20 may be spaced apart from the covers 18 to create forward airflow channels 22A, 22B. In this manner, portions 48A, 48B of the exemplary closed loop airflow 25 may extend within each of the forward airflow channels 22, between the covers 18 and the electronic display layers 20. This portion 48 of the closed loop airflow 25 may reduce heat generated from solar loading experienced at and/or through the cover(s) 18, for example, without limitation.

An illumination structure 26A, 26B may be positioned rearward of each of the electronic display layer 20A, 20B. The illumination structures 26 may comprise backlights for the electronic display layers 20. For example, without limitation, the illumination structures 26 may each comprise one or more substrates (e.g., PCB), each with a number of illumination elements (e.g., LEDs) positioned thereon which, when activated, shine light at and/or through the electronic display layers 20. The illumination structures 26 may be spaced apart from the electronic display layers 20 to create secondary airflow channels 24A, 24B. In this manner, other portions 50A, 50B of the exemplary closed loop airflow 25 may extend within each of the secondary airflow channels 24, between the illumination structures 26 and the electronic display layers 20. This may enhance thermal management and/or control forces provided at the electronic display layers 20. For example, without limitation, this portion 50 of the closed loop airflow 25 may reduce heat generated from illumination structures 26. The illumination structures 26 need not necessarily include illumination elements, such as where self-illuminating electronic displays are utilized (e.g., OLED). The secondary airflow channels 24 may extend at least substantially (e.g., within 20 degrees) parallel with the forward airflow channels 22, at least in part.

In exemplary embodiments, without limitation, the portions 48A, 50A, 48B, 50B of the exemplary closed loop airflow 25 within the respective side assemblies 14A, 14B may extend within each of the forward airflow channels 22A, 22B and secondary airflow channels 24A, 24B in at least substantially (e.g., within 20 degrees) opposite directions.

Open loop airflow channels 30A, 30B may be provided in each of the side assemblies 14A, 14B, though such is not necessarily required. Rear panels 32A, 32B may be provided, each of which is located rearward of, and spaced apart from, a respective one of the illumination structure 26A, 26B and/or forms a rear portion of the respective one of the open loop airflow channels 30A, 30B and/or the side assemblies 14A, 14B.

A corrugated layer 28A, 28B may optionally be provided within each of the open loop airflow channels 30A, 30B. The corrugated layer 28 may increase surface area within the channels 30. The open loop airflow channels 30 may be fluidly connected to the intakes/exhausts 16. The open loop airflow channels 30 may provide cooling for the illumination structures 26, which may normally provide a significant heat source, by way of non-limiting example.

Septa 36A1, 36A2, 36B1, 36B2 may extend from the side assemblies 14 and/or framework 12 to direct airflow exiting the forward airflow channels 22 and/or secondary airflow channels 24, which may be at least partially combined, toward a common heat exchanger 38 located between the side assemblies 14. In exemplary embodiments, the common heat exchanger 38 is fixed to the framework 12. The septa 36 may be fixed to one or more of: the common heat exchanger 38, the framework 12, and a respective one of the side assemblies 14. The septa 36 and/or heat exchanger 38 may serve as partitions within the space between the side assemblies 14 and within the framework 12, such as to compartmentalize and/or divide the space. The septa 36 may confine airflow traveling into and/or out of the heat exchanger 38 for example, without limitation.

In exemplary embodiments, a first one of the septa 36A1, 36B1 associated with a respective one of the side assemblies 14A, 14B extends from the respective one of the side assemblies 14A, 14B to the heat exchanger 38 and a second one of the one of the septa 36A2, 36B2 associated with the respective one of the side assemblies 14A, 14B extends from the structural framework 12 to the heat exchanger 38. The septa 36 may extend at non-parallel, non-perpendicular angle(s) relative to a face of the side assemblies 14 in exemplary embodiments, without limitation.

The heat exchanger 38 may comprise a multi-layer heat exchanger. Preferably, the heat exchanger 38 comprises alternating layers for portions 54B, 54A of the closed loop airflow 25 and open loop airflow. Preferably, the alternating layers are arranged for flow primarily in generally (e.g., within 20 degrees) perpendicular directions from one another. For example, without limitation the closed loop airflow 25 may travel primarily in a generally horizontal direction while open loop airflow may travel primarily in a generally vertical direction.

In exemplary embodiments, without limitation, the partitions 36 may direct the airflow to a distal portion of heat exchanger 38 relative to the respective side assembly 14 from which the airflow is exiting. The airflow 54B may flow through one or more layers of the heat exchanger 38. One or more of the layers of the heat exchanger 38, and/or the septa 36, may serve to separate a first portion 54B of the closed loop airflow 25 exiting the first side assembly 14A from a second portion 54A of the closed loop airflow 25 exiting the second side assembly 14B such that the first and second portions 54A, 54B of the closed loop airflow 25 within the heat exchanger 38 are provided in a generally counter flow type arrangement.

Airflow exiting the heat exchanger 38 may be at least partially recombined and extend through rear channels 46A 46B located rearward of the side assemblies 14A, 14B, within the framework 12, and outside of the heat exchanger 38. Such travel may be further confined and/or directed, at least in part, by the septa 36. In exemplary embodiments, without limitation, these portions 56A, 56B of the closed loop airflow 25 may extend over and/or under electronic components 44A, 44B. The electronic components 44A, 44B comprise one or more electronics (e.g., microchips, power supplies, video players, network connectivity devices, sensors, combinations thereof, or the like). The electronic components 44A, 44B may be mounted to substrates which are connected to, and spaced apart from, the rear panels 32. In other exemplary embodiments, without limitation, the electronic components 44A, 44B are directly mounted to the rear panels 32. The general bend in the closed loop airflow pathway 25 from the heat exchanger 38 to the fans 40 may cause the portion 56 of the circulating gas in the closed loop airflow pathway 25 to contact the electronic components 44 and/or a rear surface of the open loop channel 30 and/or rear panel 32, such as to enhance heat transfer.

In exemplary embodiments, septa 36A1 and 36A2 define, at least in part, a first channel 34A for a portion 52A of the closed loop airflow 25 exiting the forward airflow channel 22A and/or the secondary airflow channel 24A of the first side assembly 14A and entering a first portion of the common heat exchanger 38 as airflow portion 54A. Septa 36A1 may extend from a portion of the framework 12 forming a first side of the unit 10 to a layer of the common heat exchanger 38 proximate to the first side assembly 14A. Septa 36A2 may be spaced apart from septa 36A1. Septa 36A2 may extend from the illumination structure 26A of the first side assembly 14A to a mid-layer of the common heat exchanger 38 separating the first and second airflow portions 54A, 54B within the common heat exchanger 38. Septa 36B1 and 36B2 may define, at least in part, a second channel 34B for a portion 52B of the closed loop airflow 25 exiting the forward airflow channel 22B and/or the secondary airflow channel 24B of the second side assembly 14B and entering a second portion of the common heat exchanger 38 as airflow portion 54B. Septa 36B1 may extend from a portion of the framework 12 forming a second side of the unit 10 to a layer of the common heat exchanger 38 proximate to the second side assembly 14B. Septa 36B2 may be spaced apart from septa 36B1. Septa 36B2 may extend from the illumination structure 26B of the second side assembly 14B to the mid-layer of the common heat exchanger 38 separating the first and second airflow portions 54A, 54B within the common heat exchanger 38. Septa 36A1, 36A2 may be on opposing sides of the common heat exchanger 38 from septa 36B1, 36B2.

One or more fans 40A, 40B may be provided within each of the rear channels 46A, 46B. For example, without limitation, each of the fans 40 may be connected to the rear panel 32 of the respective side assembly 14. The fans 40 may comprise a housing 42 that preferably extends between an entrance to the respective fan 40 and the respective side assembly 14, such as to guide the circulating air exiting the fan 40 towards the respective forward channel 22 and secondary channel 24 of the respective side assembly 14. In exemplary embodiments, without limitation, the fans 40 comprise centrifugal type fans, though such is not necessarily required.

The open loop airflows extending within the unit 10, such as within the open loop airflow channels 30A, 30B and heat exchanger 38 may be entirely separate and have separate intakes and/or exhausts 16, for example, or may be common, at least in part, any may share at least some of the intakes and/or exhausts 16.

The closed loop airflow pathways 25 illustrated is intended to convey a generalized, exemplary flow pathway and/or airflow velocities.

While the terms closed loop, circulating gas, or similar are sometimes used herein, the display unit 10, airflow pathways, and/or individual passageways, channels, etc. need not necessarily be hermetically sealed. Preferably, the separation between a least the closed loop airflow pathways 25 and the open loop airflow pathway(s) and/or ambient environment is sufficient to meet or exceed one or more of ingress protection (IP) 65, 66, 67, or more stringent, such as in accordance with the standards advanced by the International Electrotechnical Commission of Geneva, Switzerland (https://www.iec.ch/ip-ratings). Gaskets, caulking, solid materials, combinations thereof, or the like may be used to accomplish such separation and/or sealing.

The open loop airflow pathway(s) may be those in direct fluid connection with the ambient environment.

The disclosed embodiment(s) may facilitate adequate thermal management (e.g., cooling) during normal operations for a wide variety of environmental conditions. Alternatively, or additionally, the disclosed embodiment(s) may facilitate a relatively small footprint and/or occupation of space, which may be particularly important for installation in a small space (e.g., narrow sidewalk) or otherwise congested population center which space is highly valued. The disclosed embodiment(s) may be particularly suitable for relatively narrow, elongated units 10, by way of non-limiting example, which may otherwise provide insufficient surface area for heat exchange.

Alternatively, or additionally, the disclosed units 10 may not require any pass-through devices for the closed loop airflow pathway 25, at least, which can be difficult to adequately seal and provide certain complexities in manufacturing and/or maintenance.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention.

Certain operations described herein may be performed by one or more electronic devices. Each electronic device may comprise one or more processors, electronic storage devices, executable software instructions, combinations thereof, and the like configured to perform the operations described herein. The electronic devices may be general purpose computers or specialized computing devices. The electronic devices may comprise personal computers, smartphones, tablets, databases, servers, or the like. The electronic connections and transmissions described herein may be accomplished by one or more wired or wireless connectively components (e.g., routers, modems, ethernet cables, fiber optic cable, telephone cables, signal repeaters, and the like) and/or networks (e.g., internets, intranets, cellular networks, the world wide web, local area networks, and the like). The computerized hardware, software, components, systems, steps, methods, and/or processes described herein may serve to improve the speed of the computerized hardware, software, systems, steps, methods, and/or processes described herein. The electronic devices, including but not necessarily limited to the electronic storage devices, databases, controllers, or the like, may comprise and/or be configured to hold, solely non-transitory signals.

What is claimed is:

1. A display assembly comprising:
opposing side assemblies forming connected portions of a structural framework, each side assembly comprising a cover, an electronic display, and a channel for airflow, wherein the electronic display and the channel are located rearward of the cover;
a common heat exchanger positioned rearward of each of the side assemblies;
septa airflow channels extending from the side assemblies and/or the structural framework to the heat exchanger; and
rear airflow channels extending between the heat exchanger and the side assemblies, each further defined, at least in part, by at least one of the septa airflow channels.

2. The display assembly of claim 1 further comprising:
a closed airflow pathway comprising the channels of the side assemblies, the septa airflow channels, and the heat exchanger, said closed airflow pathway forming a circuit which includes fluidly separated flow through a plurality of layers of the heat exchanger.

3. The display assembly of claim 2 further comprising:
one or more fans, which when activated, move circulating gas through the closed airflow pathway, including through different one or ones of the plurality of layers of the heat exchanger in different directions in a fluidly separated manner.

4. The display assembly of claim 3 wherein:
the one or more fans, when activated, move the circulating gas through the channels of the side assemblies in different directions and through the rear airflow channels in different directions.

5. The display assembly of claim 2 wherein:
the heat exchanger comprises a second plurality of layers, fluidly separated from the plurality of layers, and fluidly connected to an ambient environment.

6. The display assembly of claim 5 wherein:
the second plurality of layers are alternately arranged with the plurality of layers.

7. The display assembly of claim 5 wherein:
the side assemblies each comprise a second channel located rearward of the electronic display and fluidly connected to the ambient environment.

8. The display assembly of claim 7 wherein:
the electronic displays of the side assemblies each comprise a liquid crystal layer;
each of the side assemblies further comprise:
an illumination structure located rearward of the liquid crystal layer for backlighting the liquid crystal layer; and
a rear panel located rearward of the illumination structure; and
the second channels of the side assemblies are located rearward of the illumination structures and forward of the rear panels thereof.

9. The display assembly of claim 8 wherein:
the channels of the side assemblies are located forward of the liquid crystal layers thereof.

10. The display assembly of claim 9 wherein:
each of the side assemblies further comprise a third channel located between the liquid crystal layers and the illumination structures thereof, said third channels forming part of the closed airflow pathway.

11. The display assembly of claim 7 further comprising:
corrugated layers, each located within one of the second channels.

12. The display assembly of claim 7 wherein:
the closed airflow pathway is fluidly separated from the ambient environment, the second plurality of layers of the heat exchanger, and the second channel of the side assemblies in a manner at least as well sealed as ingress protection code 65.

13. The display assembly of claim 1 further comprising:
electronics for operating the display assembly, at least a portion of which are located within the rear airflow channels.

14. The display assembly of claim 13 further comprising:
substrates, provided at, and spaced apart from, the rear surfaces of the side assemblies, wherein at least some of the portion of the electronics are mounted to the substrates.

15. The display assembly of claim 1 further comprising:
septa extending from different sides of the heat exchanger and/or of the structural framework.

16. The display assembly of claim 15 wherein:
each of the septa extend, at least in part, at a non-parallel, non-perpendicular angle relative to a forward surface of the covers.

17. The display assembly of claim 15 wherein:
the septa are provided in spaced apart sets;
a first septa in each set of the septa extends from the structural framework to a respective end of a layer of the heat exchanger such that the first septa in each set of the septa extends to a different end of the layer of the heat exchanger; and
a second septa in each set of the septa extends from the respective one of the side assemblies to a mid-layer of the layers of the heat exchanger.

18. The display assembly of claim 1 wherein:
the structural framework is configured for mounting to a sidewalk location.

19. A display assembly comprising:
a first and second side assembly connected to a first and second side of a structural framework, respectively, each of the first and second side assembly comprising a cover, an electronic display positioned rearward of the cover, and a channel for airflow extending along the electronic display;
a shared heat exchanger positioned rearward of, and spaced apart from, the side assemblies and within the structural framework, said heat exchanger comprising a plurality of layers;
a first set of septa extending from the first side assembly and/or a first side of the structural framework to a first side of the heat exchanger to form, at least in part, a first airflow channel (“first septa airflow channel”) extending from the channel of the first side assembly to a first subset of the layers of the heat exchanger;
a second set of septa extending from the second side assembly and/or a second side of the structural framework to a second side of the heat exchanger to form, at least in part, a second airflow channel (“second septa airflow channel”) extending from the channel of the second side assembly to a second subset of the layers of the heat exchanger;
a first rear channel between the first side assembly and first side of the heat exchanger;
a second rear channel between the second side assembly and second side of the heat exchanger; and
a closed airflow pathway forming a circuit comprising the channels of the first and second side assemblies, the layers of the heat exchanger, the first and second septa airflow channels, and the first and second rear channels.

20. A display assembly comprising:
a first and second side assembly connected to first and second sides of a structural framework, respectively, each of the first and second side assemblies comprising a cover, an electronic display positioned rearward of the cover, and a channel for airflow located rearward of the cover and forward of the electronic display;
a heat exchanger positioned rearward of, and spaced apart from, the side assemblies and within the structural framework, said heat exchanger comprising a first plurality of layers and a second plurality of layers, the second plurality of layers being fluidly connected to an ambient environment;
septa comprising a first septa extending from a first interior surface of the structural framework to a first one of the first plurality of layers of the heat exchanger, a second septa spaced apart from the first septa and extending from a rear surface of the first side assembly to a mid-layer of the first plurality of layers of the heat exchanger, a third septa extending from a second interior surface of the structural framework to a final one of the first plurality of layers of the heat exchanger, and a fourth septa spaced apart from the third septa and extending from a rear surface of the second side assembly to a same or different mid-layer of the first plurality of layers of the heat exchanger, the first and second septa forming, at least in part, a first airflow channel between the channel of the first side assembly and a first subset of the first plurality of layers of the heat exchanger and the third and fourth septa forming, at least in part, a second airflow channel between the channel of the second side assembly and a second subset of the first plurality of layers of the heat exchanger;
a first and second rear channel provided between the first and second side assembly, respectively, the heat exchanger, and the first and third septa, respectively; and
a closed airflow pathway forming a circuit comprising the channels of the first and second side assemblies, the first plurality of layers of the heat exchanger, the first and second airflow channels formed, at least in part, by the septa, and the first and second rear channels.
